(19) United States
(12) Patent Application Publication
(10) Pub. No.: US 2014/0113452 A1
(43) Pub. Date: Apr. 24, 2014

(54) WAFER EDGE TRIMMING METHOD

(71) Applicant: UNITED MICROELECTRONICS CORP., Hsinchu (TW)

(72) Inventors: Chu-Fu LIN, Kaohsiung (TW); Chung-Sung CHANG, Kaohsiung (TW); Chun-Hung CHEN, Tainan (TW); Ming-Tse LIN, Hsinchu (TW); Yung-Chang LIN, Taichung (TW)

(73) Assignee: UNITED MICROELECTRONICS CORP., HSINCHU (TW)

(21) Appl. No.: 13/654,425

(22) Filed: Oct. 18, 2012

(51) Int. Cl. H01L 21/306

(52) U.S. Cl. 438/706; 257/E21.215

(57) ABSTRACT

A wafer edge trimming method comprises steps as follows: Firstly, an etch-resistant layer is formed on a surface of a wafer. A wet treatment process is then performed to remove a portion of the etch-resistant layer, so as to expose a portion of the surface adjacent to an edge of the wafer. Subsequently, an etching process is performed to remove a portion of the wafer that is not covered by the remained etch-resistant layer.

### FIELD OF THE INVENTION

The present invention relates to a method for fabricating a semiconductor device, and more particularly to a wafer edge trimming method.

### BACKGROUND OF THE INVENTION

Typically, most wafers may have a bevel edge resulted by a wafer thinning process. When the mechanical stress or thermal stress generated by a semiconductor device fabricating process is imposed to the wafer, the existence of the bevel may cause uneven stress being subjected to the edge of the wafer, thus wafer crack and delamination may be triggered. Accordingly, a wafer edge trimming process is desired to remove the bevel edge before the semiconductor device fabricating process is carried out.

However, a conventional wafer edge trimming process which utilizes a grinding wheel to polish the bevel edge may result in producing particles to contaminate the subsequent processes. Besides, the wafer may be damaged or cracked off due to the mechanical stress imposed by the grinding wheel.

Therefore, there is a need of providing an improved wafer edge trimming method to obviate the drawbacks encountered from the prior art.

### SUMMARY OF THE INVENTION

In accordance with an aspect, the present invention provides a wafer edge trimming method, wherein the wafer edge trimming method comprises steps as follows: Firstly, an etch-resistant layer is formed on a surface of a wafer. A wet treatment process is then performed to remove a portion of the etch-resistant layer, so as to expose a portion of the surface adjacent to an edge of the wafer. Subsequently, an etching process is performed to remove a portion of the wafer that is not covered by the remained etch-resistant layer.

In one embodiment of the present invention, the etch-resistant layer is an adhesive layer.

In one embodiment of the present invention, the wafer edge trimming method further comprises steps of using the adhesive layer to bond the wafer onto a handle wafer after the etching process is carried out.

In one embodiment of the present invention, the adhesive layer comprises acrylic base resin. In one embodiment of the present invention, an organic solvent comprising ketones, esters, aromatics, xylene or the arbitrary combinations thereof is used to remove the adhesive layer during the wet treatment process.

In one embodiment of the present invention, the etch-resistant layer is a photo-resist layer. In one embodiment of the present invention, the wafer edge trimming method further comprises steps of bonding the wafer onto a handle wafer and performing a wafer thinning process on a backside of the wafer prior to the formation of the etch-resistant layer.

In one embodiment of the present invention, the wet treatment process is a wafer edge cleaning process.

In one embodiment of the present invention, the wafer edge trimming method further comprises performing an exposure and development process on the photo-resist layer before the wet treatment process is carried out. In one embodiment of the present invention, the wet treatment process comprises steps of applying deionized water (DI water) to remove the developed portion of the photo-resist layer.

In one embodiment of the present invention, the etching process is a dry etching process.

In accordance with the aforementioned embodiments of the present invention, a wafer edge trimming method is provided. Wherein an etch-resistant layer is firstly formed on a surface of a wafer; a wet treatment process is then performed to remove a portion of the etch-resistant layer, so as to expose a portion of the surface adjacent to the edge of the wafer; and subsequently an etching process is carried out to remove the portion of the wafer that is not covered by the remained etch-resistant layer. Such that the bevel edge of the wafer cane be trimmed off.

Since, an etching process is adopted to take the place of the conventional grinding wheel polish to trim the bevel edge of the wafer off, thus the problems of particle contamination, wafer crack and delamination can be obviated, and the yield of the semiconductor device can be improved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1D are diagrammatic sketches illustrating a wafer edge trimming method in accordance with one embodiment of the present invention; and

FIGS. 2A to 2E are diagrammatic sketches illustrating a wafer edge trimming method in accordance with another embodiment of the present invention.

### DETAILED DESCRIPTION OF PREFERRED EMBODIMENTS

A wafer edge trimming method is provided by the present invention to solve problems of particle contamination, wafer cracking and delamination due to having a bevel edge on a wafer. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

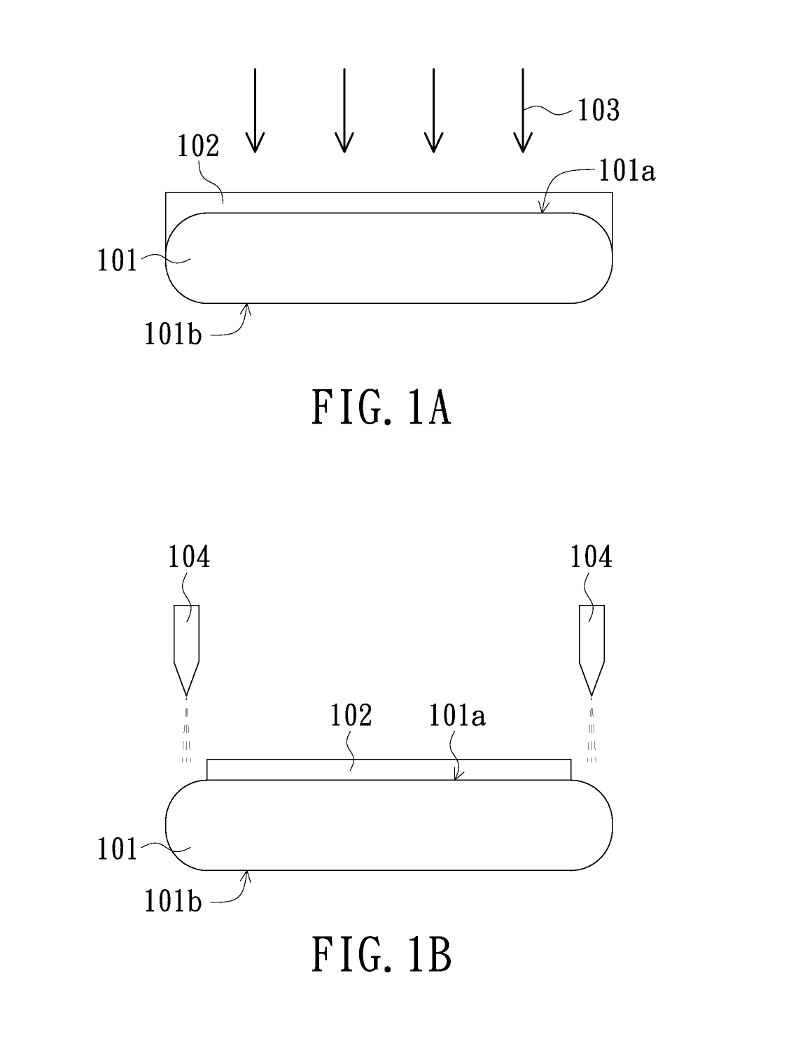

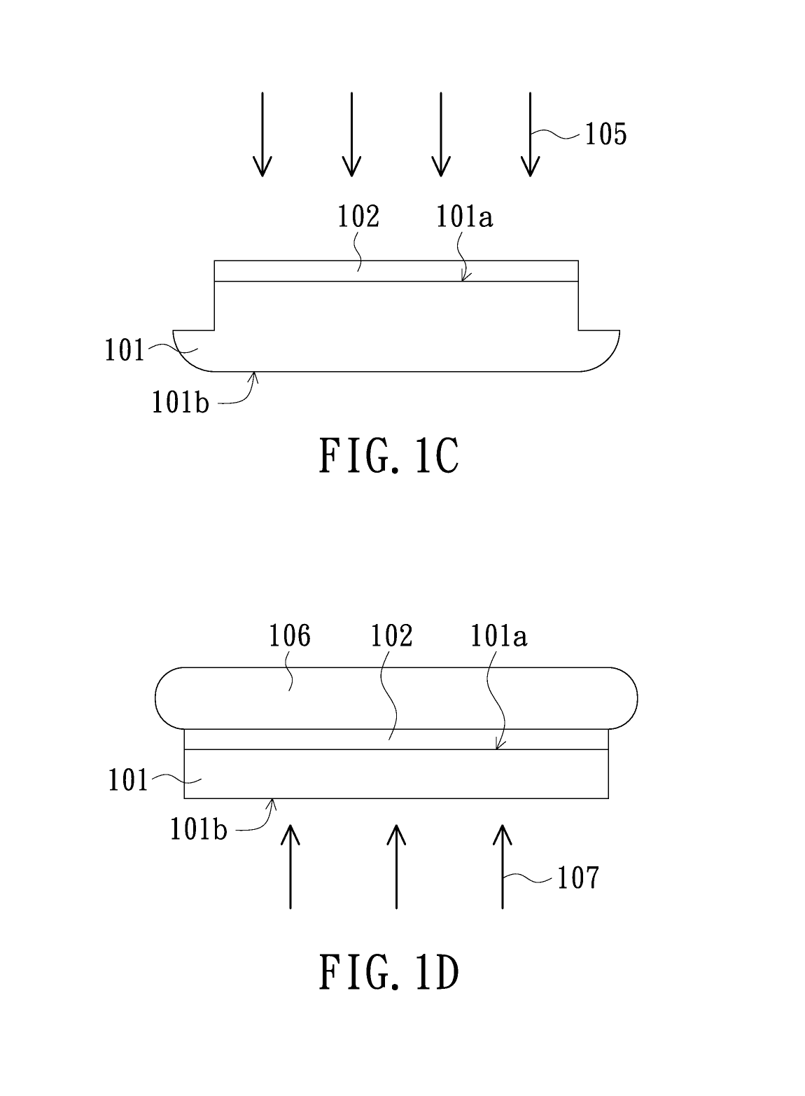

FIGS. 1A to 1D are diagrammatic sketches illustrating a wafer edge trimming method in accordance with one embodiment of the present invention, wherein the wafer edge trimming method comprises steps as follows:

An etch-resistant layer 102 is firstly formed on a surface of a wafer 101. In some embodiments of the present invention, the wafer 101 may be a silicon wafer, and the etch-resistant layer 102 may be formed ether on a front side 101a or on a backside 101b of the wafer 101. In the present embodiment, the etch-resistant layer 102 is formed on the front side 101a of the wafer 101.

In some embodiments of the present invention, the etch-resistant layer 102 may be an adhesive layer comprising acrylic base resin. For example, the etch-resistant layer 102 is made of polymer materials such as LC3200/4200/5200 provided by Minnesota Mining & Manufacturing Company ( 3M™ Company). And the formation of the etch-resistant layer 102 may comprise coating an adhesive material on the front side 101a of the wafer 101 by a printing press process, a paste process or a spin coating process, and hardening the adhesive material coated on the front side 101a of the wafer 101 by a wafer baking/curing process 103 (see step shown in FIG. 1A).

Next, a wet treatment process 104 is then performed to remove a portion of the etch-resistant layer 102 adjacent to the edge of the wafer 101, so as to expose a portion of the front side 101a adjacent to the edge of the wafer 101 (see step shown in FIG. 1B). In some embodiments of the present invention, the wet treatment process 104 may be a wafer edge cleaning process. Preferably, a wafer edge cleaning apparatus is adopted to drive the wafer 101 to be rotating, and from which a solvent available for dissolving the etch-resistant layer 102 is sprayed on the etch-resistant layer 102, so as to remove the portion of the etch-resistant layer 102 adjacent to the edge of the wafer 101. For example, in the present embodiment, the etch-resistant layer 102 adjacent to the edge of the wafer 101 is removed by an organic solvent comprises ketones, esters, aromatics, xylene or the arbitrary combinations thereof.

Subsequently, an etching process 105 is performed by using the remained etch-resistant layer 102 as a mask to remove a portion of the wafer 101 that is not covered by the remained etch-resistant layer 102 (see step shown in FIG. 1C). In some embodiments of the present invention, a dry etching process 105 is performed to remove the portion of the wafer 101. In the present embodiment, the dry etching process may be a plasma etching process.

After the etching process 105 is carried out, the wafer 101 is bonded onto a handle wafer 106 by an adhesive layer. In the present embodiment, the etch-resistant layer 102 can serve as the adhesive layer for bonding the wafer 101 onto the handle wafer 106. By adopting this approach, the wafer bonding process can be simplified, and at the same time, the processing cost can be reduced. A wafer thinning process 107 is then performed on the backside 101b of the wafer. Subsequently, several downstream steps are performed to complete the fabrication process of a semiconductor device.

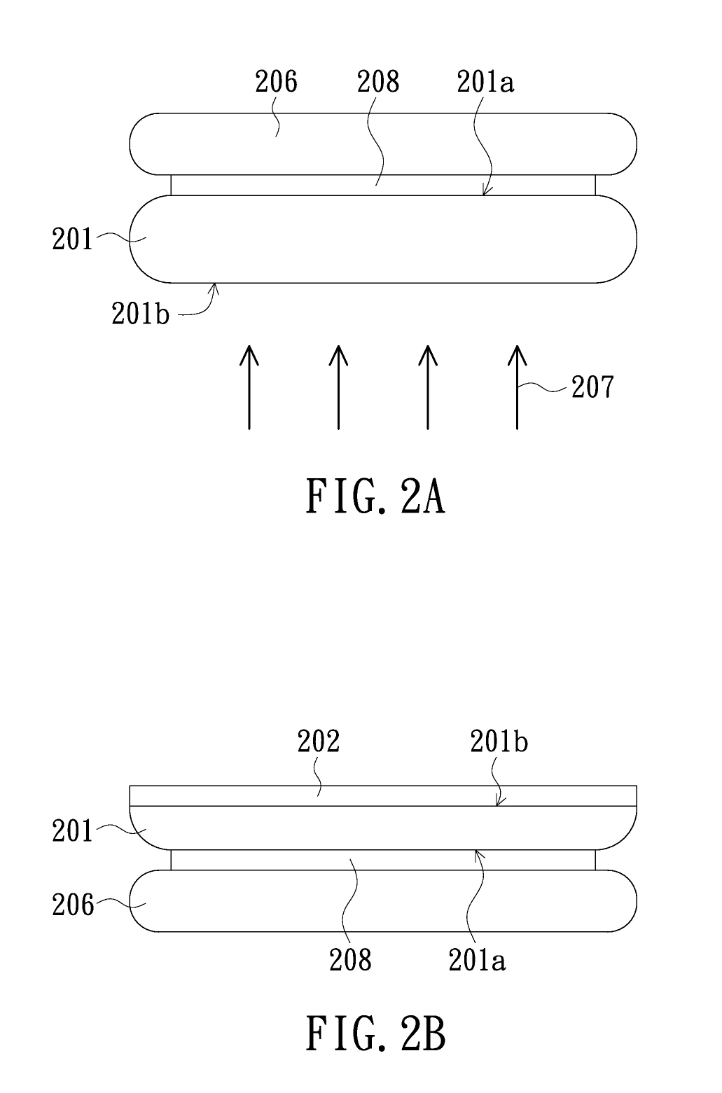

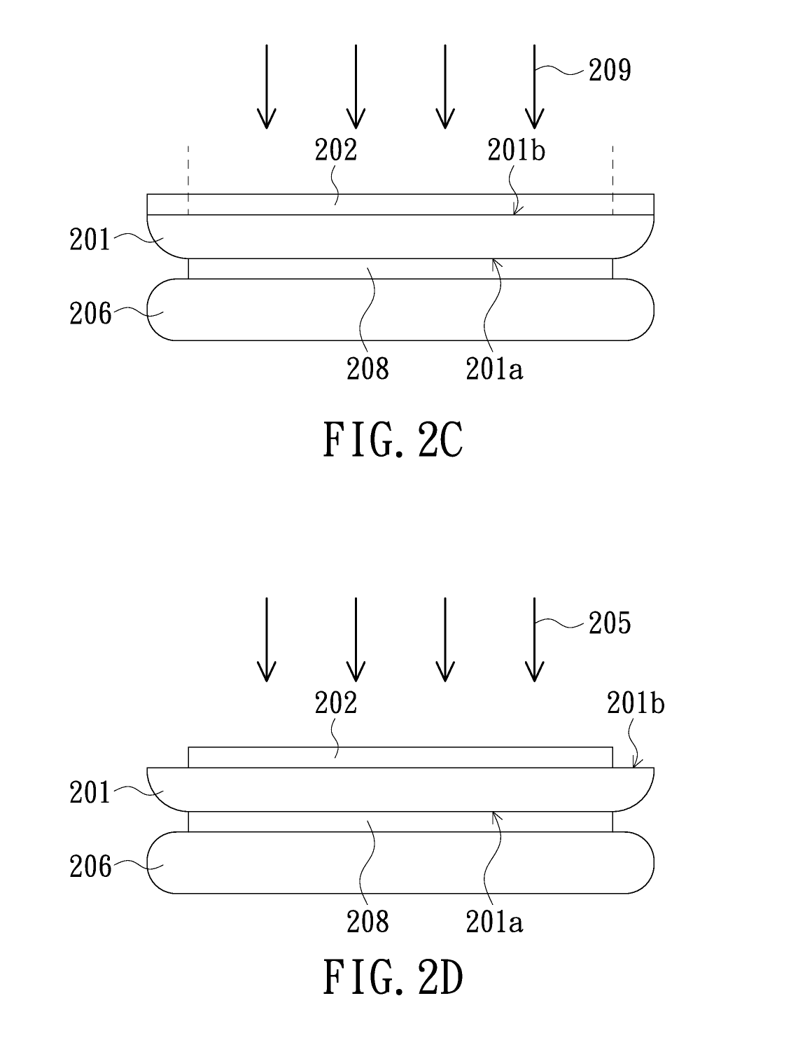

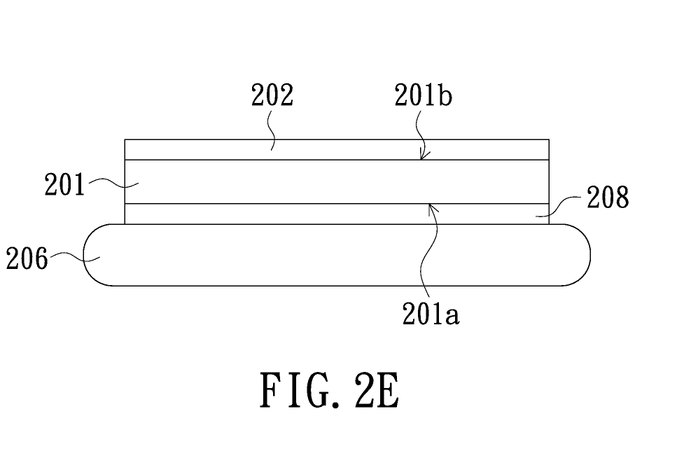

FIGS. 2A to 2E are diagrammatic sketches illustrating a wafer edge trimming method in accordance with another embodiment of the present invention, wherein the wafer edge trimming method is applied to trim a bevel edge of a wafer 201 off after the wafer 201 is subjected to a wafer thinning process. The wafer edge trimming method comprises steps as follows:

Firstly, an adhesive layer 208 is coated on a front side 201a of the wafer 201. A handle wafer 206 is then bonded onto the wafer 201 by the adhesive layer 208. Next, a wafer thinning process 207 is performed on a backside 201b of the wafer 201 to thin down the wafer 201 (see step 2A).

Subsequently, an etch-resistant layer 202 is formed on the backside 201b of the wafer 201 that has been subjected to the wafer thinning process 207 (see step shown in FIG. 2B). In some embodiments of the present invention, the etch-resistant layer 202 may include organic materials or may be made of a photo-resist layer, such as an ArF photo-resist layer, a silicon-containing hard mask (SHB) layer or an I-line photo-resist layer.

When a photo-resist layer is adopted as the etch-resistant layer 202, an optional exposure and development process 209 may be performed on the etch-resistant layer 202 (see step shown in FIG. 2C), and the developed portion of the etch-resistant layer 202 is removed by a subsequent wet treatment process 205, whereby a portion of the backside 201b adjacent to the edge of the wafer 201 can be exposed (see step shown in FIG. 2D). In the present embodiment, the wet treatment process 205 comprises steps of applying deionized water to remove the developed portion of the etch-resistant layer 202.

It is worthy to note that since the wafer edge trimming method required lower etching accuracy, in comparison with the other etching process of the semiconductor device fabrication process, thus the exposure and development process 209 preferably may be omitted. For example, in some embodiments of the present invention, the wet treatment process 204 (such as the wafer edge cleaning process depicted in FIG. 1 step 1B) may be directly performed by using DI water or a solvent available for dissolving the etch-resistant layer 202 to remove the portion of the etch-resistant layer 202 adjacent to the edge of the wafer 201 without utilizing any reticle mask, such that the wafer edge trimming process can be simplified and the processing cost can be significantly reduced.

Thereafter, an etching process 205, such as a plasma etching process, is performed by using the remained etch-resistant layer 202 as a mask to remove a portion of the wafer 201 that is not covered by the remained etch-resistant layer 202 (see step shown in FIG. 2E). Subsequently, several downstream steps are performed to complete the fabrication process of a semiconductor device.

In accordance with the aforementioned embodiments of the present invention, a wafer edge trimming method is provided. Wherein an etch-resistant layer is firstly formed on a surface of a wafer; a wet treatment process is then performed to remove a portion of the etch-resistant layer, so as to expose a portion of the surface adjacent to the edge of the wafer; and subsequently an etching process is carried out to remove the portion of the wafer that is not covered by the remained etch-resistant layer, such that the bevel edge of the wafer can be trimmed off.

Since, an etching process is adopted to take the place of the conventional grinding wheel polish to trim off the edge bevel of the wafer, thus the problems of particle contamination and wafer cracking and delamination can be obviated, and the yield of the semiconductor device can be improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wafer edge trimming method comprising:
forming an etch-resistant layer on a surface of a wafer;
performing a wet treatment process to remove a portion of the etch-resistant layer, so as to expose a portion of the surface adjacent to an edge of the wafer and form an remained etch-resistant layer; and
performing an etching process to remove a portion of the wafer that is not covered by the remained etch-resistant layer.

2. The wafer edge trimming method according to claim 1, wherein the etch-resistant layer is an adhesive layer.

3. The wafer edge trimming method according to claim 2, further comprising steps of providing a handle wafer, and using the adhesive layer to bond the wafer onto the handle wafer after the etching process is carried out.

4. The wafer edge trimming method according to claim 2, wherein the adhesive layer comprises acrylic base resin.

5. The wafer edge trimming method according to claim 4, wherein the wet treatment process comprises using an organic solvent comprising ketones, esters, aromatics, xylene or the arbitrary combinations thereof to remove the adhesive layer.

6. The wafer edge trimming method according to claim 2, wherein the etch-resistant layer is a photo-resist layer.

7. The wafer edge trimming method according to claim 6, prior to the formation of the etch-resistant layer, further comprising:
providing a handle wafer;
bonding the wafer onto the handle wafer; and
performing a wafer thinning process on a backside of the wafer.

8. The wafer edge trimming method according to claim 6, wherein the wet treatment process comprises a wafer edge cleaning process.

9. The wafer edge trimming method according to claim 6, further comprising performing an exposure and development process on the photo-resist layer before the wet treatment process is carried out.

10. The wafer edge trimming method according to claim 9, wherein the wet treatment process comprises applying deionized water to remove the developed portion of the photo-resist layer.

11. The wafer edge trimming method according to claim 1, wherein the etching process is a dry etching process.
